(19) United States
(12) Patent Application Publication
(10) Pub. No.: US 2021/0051814 A1
(43) Pub. Date: Feb. 18, 2021

(54) BLIND-MATE ADAPTER FOR SERVERS AND SERVER RACKS

(71) Applicant: Dell Products L.P., Round Rock, TX (US)

(72) Inventors: Walt R. CARVER, Round Rock, TX (US); Shane G. KAVANAGH, Leander, TX (US); Joseph Andrew VIVIO, Seattle, WA (US)

(73) Assignee: Dell Products L.P., Round Rock, TX (US)

(21) Appl. No.: 16/542,047

(22) Filed: Aug. 15, 2019

(51) Int. Cl. H05K 7/14; H05K 7/18; G06F 13/40

(52) U.S. Cl. CPC H05K 7/1454; H05K 7/1492; G06F 13/4081; H05K 7/183; G06F 13/409; H05K 7/1489

(57) ABSTRACT

An apparatus for coupling an information handling system server to an electrical infrastructure of an information handling system rack may include a mechanical housing, a server-facing interface on a first side of the mechanical housing and comprising one or more server-facing electrical connectors each configured to electrically couple to a respective electrically-conductive feature of the server, a rack-facing interface on a second side of the mechanical housing comprising one or more rack-facing electrical connectors each configured to electrically couple to a respective electrically-conductive feature of the electrical infrastructure, and an intermediate electrical interface comprising one or more electrically-conductive conduits, each electrically-conductive conduit configured to electrically couple a server-facing electrical connector to a corresponding rack-facing electrical connector in order to electrically couple electrically-conductive features of the electrical infrastructure to respective electrically-conductive features of the server when the apparatus is mechanically engaged with the server and the electrical infrastructure.

### TECHNICAL FIELD

The present disclosure relates to modular information handling systems. More specifically, embodiments of the disclosure provide systems and methods for providing a blind-mate adapter for servers and server racks to enable efficient coupling to electrical and electronic components of an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Oftentimes, information handling systems are each manufactured in a modular form factor and may be configured to be disposed in a chassis configured to receive such modular components. Such a chassis and its component modular information handling systems typically include various rails, carriers, and other mechanical components allowing for a person to add and remove the modular information handling systems and information handling resources from the chassis.

Oftentimes, particularly at remote locations within a business enterprise, it is not feasible to maintain full-time staff to configure and maintain information technology equipment. Mistakes may be made during deployment or replacement of a server (e.g., mis-wiring of a network cable), which may require service calls which may be costly and contribute to excessive down time. Accordingly, approaches that reduce or eliminate such problems are desirable.

### SUMMARY

In accordance with the teachings of the present disclosure, the disadvantages and problems associated with deployment and replacement of information handling system servers may be reduced or eliminated.

In accordance with embodiments of the present disclosure, an apparatus for coupling an information handling system server to an electrical infrastructure of an information handling system rack may include a mechanical housing, a server-facing interface on a first side of the mechanical housing and comprising one or more server-facing electrical connectors each configured to electrically couple to a respective electrically-conductive feature of the information handling system server, a rack-facing interface on a second side of the mechanical housing comprising one or more rack-facing electrical connectors each configured to electrically couple to a respective electrically-conductive feature of the electrical infrastructure, and an intermediate electrical interface comprising one or more electrically-conductive conduits, each electrically-conductive conduit configured to electrically couple a server-facing electrical connector to a corresponding rack-facing electrical connector in order to electrically couple electrically-conductive features of the electrical infrastructure to respective electrically-conductive features of the information handling system server when the apparatus is mechanically engaged with the information handling system server and the electrical infrastructure.

In accordance with these and other embodiments of the present disclosure, a method for coupling an information handling system server to an electrical infrastructure of an information handling system rack may include providing a mechanical housing, forming a server-facing interface on a first side of the mechanical housing, the server-facing interface comprising one or more server-facing electrical connectors each configured to electrically couple to a respective electrically-conductive feature of the information handling system server, forming a rack-facing interface on a second side of the mechanical housing, the rack-facing interface comprising one or more rack-facing electrical connectors each configured to electrically couple to a respective electrically-conductive feature of the electrical infrastructure, and forming an intermediate electrical interface comprising one or more electrically-conductive conduits, each electrically-conductive conduit configured to electrically couple a server-facing electrical connector to a corresponding rack-facing electrical connector in order to electrically couple electrically-conductive features of the electrical infrastructure to respective electrically-conductive features of the information handling system server when the apparatus is mechanically engaged with the information handling system server and the electrical infrastructure.

In accordance with these and other embodiments of the present disclosure, an information handling system rack may include an electrical infrastructure, an information handling system server, and a blind-mate connector for coupling an information handling system server to an electrical infrastructure of an information handling system rack. The blind-mate connector may include a mechanical housing, a server-facing interface on a first side of the mechanical housing and comprising one or more server-facing electrical connectors each configured to electrically couple to a respective electrically-conductive feature of the information handling system server, a rack-facing interface on a second side of the mechanical housing comprising one or more rack-facing electrical connectors each configured to electrically couple to a respective electrically conductive feature of the electrical infrastructure, and an intermediate electrical interface comprising one or more electrically-conductive conduits, each electrically-conductive conduit configured to electrically couple a server-facing electrical connector to a corresponding rack-facing electrical connector in order to electrically couple electrically-conductive features of the electrical infrastructure to respective electrically-conductive features of the information handling system server when the blind-mate connector is mechanically engaged with the information handling system server and the electrical infrastructure.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a perspective view of a chassis for receiving and housing information handling system servers, in accordance with embodiments of the present disclosure;

FIG. 2 illustrates a perspective view of an example information handling system server interfacing with a server-side blind-mate adapter, in accordance with embodiments of the present disclosure;

FIG. 3 illustrates another perspective view of an example information handling system server interfacing with a server-side blind-mate adapter, in accordance with embodiments of the present disclosure;

FIG. 4 illustrates a perspective view of a rack-side blind-mate adapter mechanically coupled to a chassis, in accordance with embodiments of the present disclosure;

FIG. 5 illustrates another perspective view of a rack-side blind-mate adapter mechanically coupled to a chassis, in accordance with embodiments of the present disclosure; and

FIG. 6 illustrates a perspective view of an example information handling system server interfacing with a server-side blind-mate adapter and rack-side blind-mate adapter, in accordance with embodiments of the present disclosure.

### DETAILED DESCRIPTION

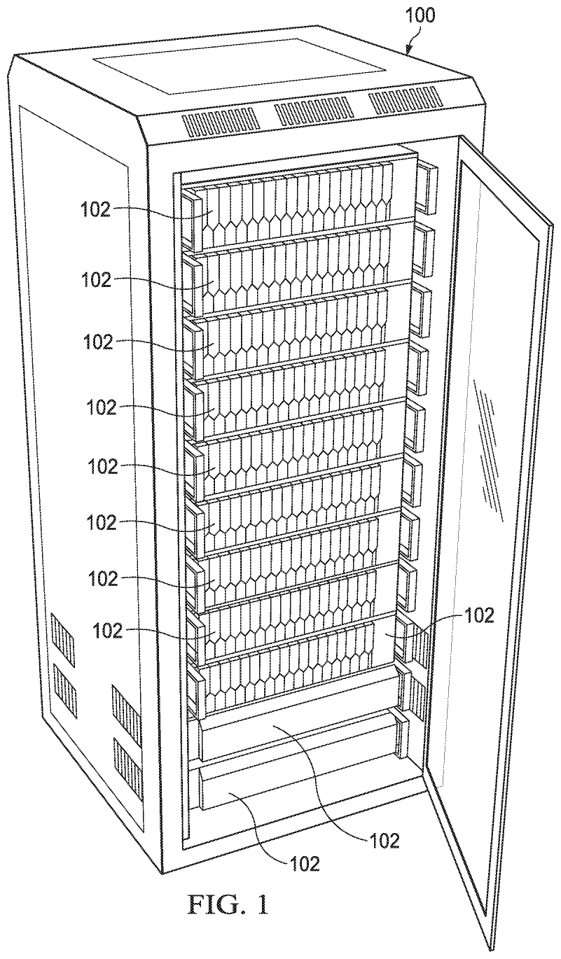

Preferred embodiments and their advantages are best understood by reference to FIGS. 1-6, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

In this disclosure, the term “information handling resource” may broadly refer to any component system, device or apparatus of an information handling system, including without limitation processors, buses, memories, input-output devices and/or interfaces, storage resources, network interfaces, motherboards, electro-mechanical devices (e.g., fans), displays, and power supplies.

FIG. 1 illustrates a perspective view of a chassis 100 for receiving modular information handling resources, in accordance with embodiments of the present disclosure. Chassis 100 may be an enclosure that serves as a container for various information handling systems and information handling resources, and may be constructed from steel, aluminum, plastic, and/or any other suitable material. Although the term “chassis” is used, chassis 100 may also be referred to as a rack, case, cabinet, tower, box, enclosure, and/or housing. In certain embodiments, chassis 100 may be configured to hold and/or provide power to a plurality of information handling system servers 102.

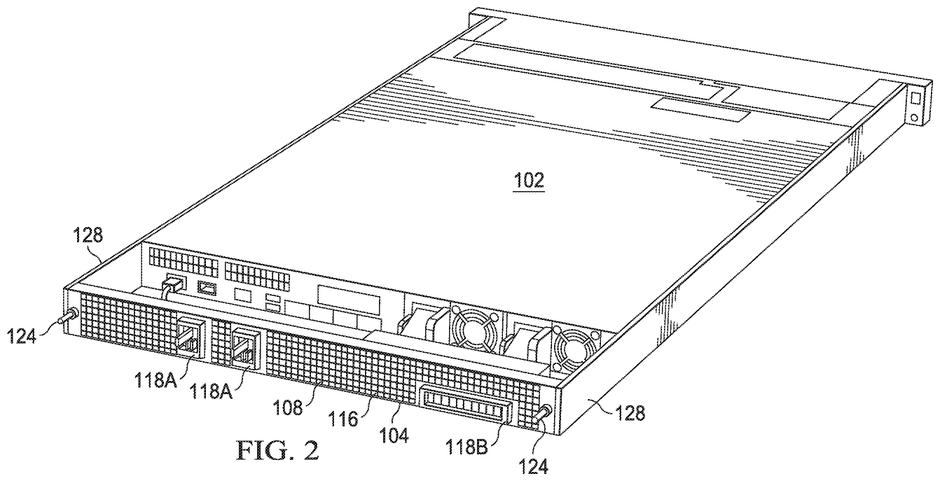

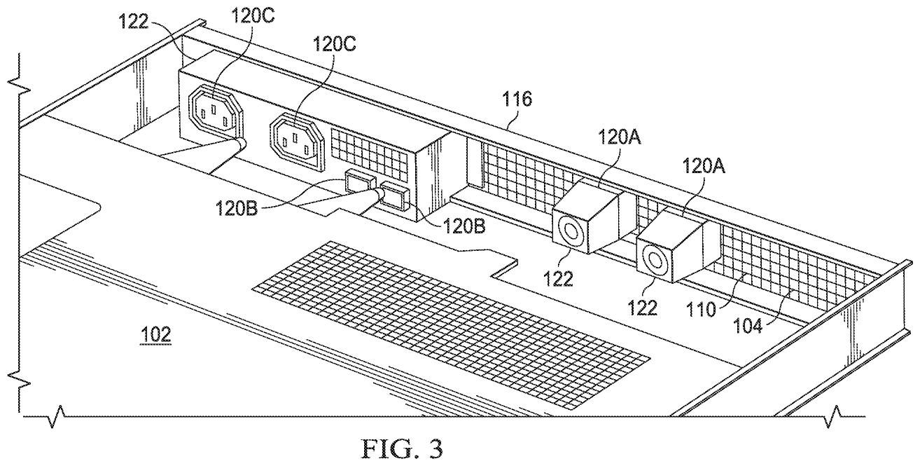

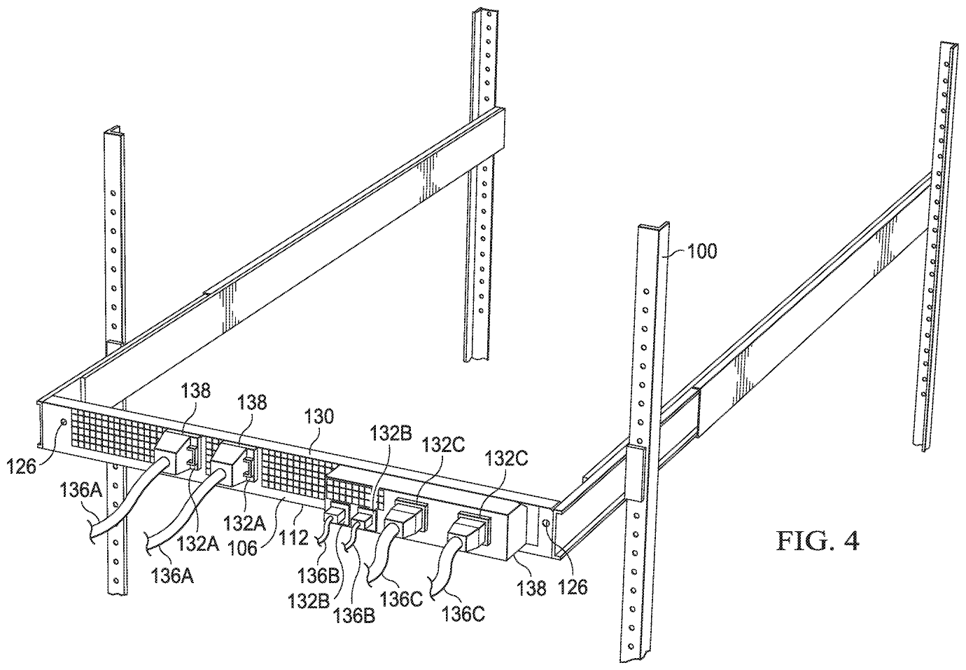

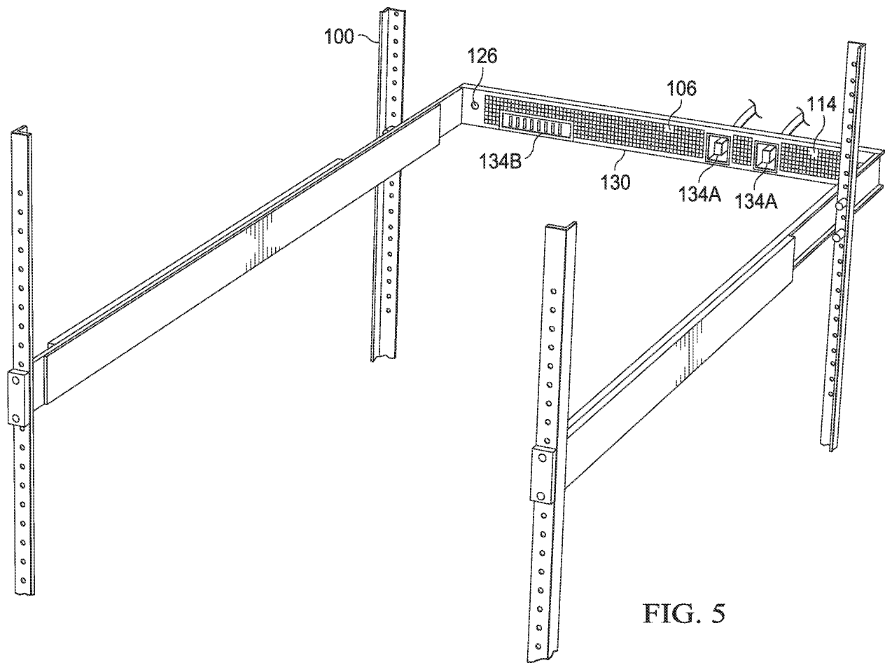

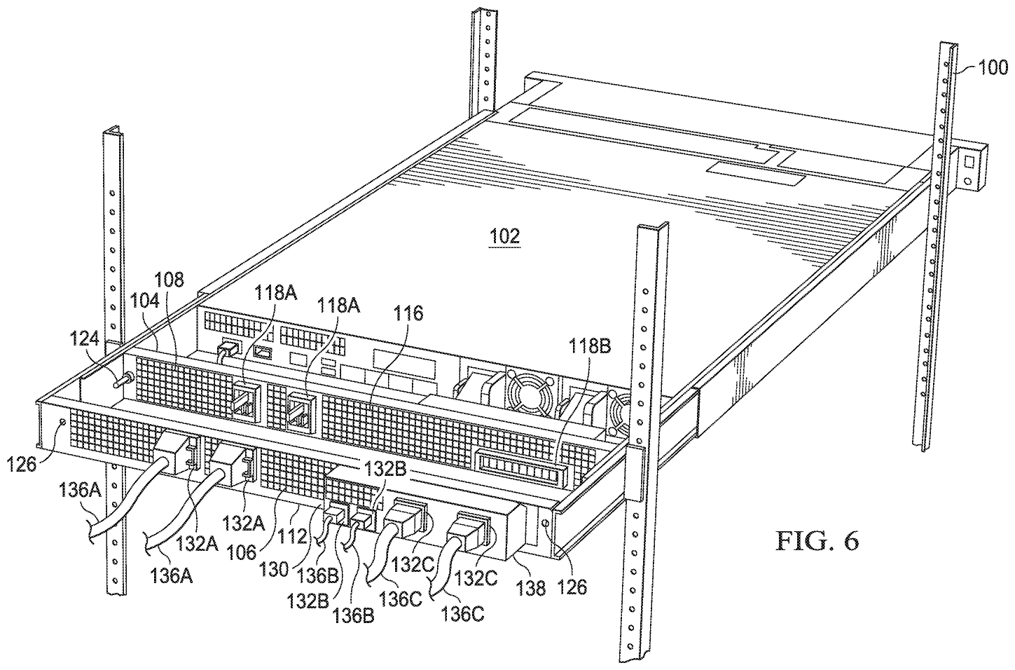

FIGS. 2-6 depict various views of selected components of an information handling system server 102, a server-side blind-mate adapter 104, a rack-side blind-mate adapter 106, and chassis 100, in accordance with embodiments of the present disclosure. For example, FIG. 2 illustrates a perspective view of an example information handling system server 102 interfacing with a server-side blind-mate adapter 104 in which features of a rack-facing side 108 of server-side blind-mate adapter 104 are visible, in accordance with embodiments of the present disclosure. FIG. 3 illustrates a perspective view of example information handling system server 102 interfacing with server-side blind-mate adapter 104, in accordance with embodiments of the present disclosure in which features of a server-facing side 110 of server-side blind-mate adapter 104 (which may be on a side of server-side blind-mate adapter 104 opposite of rack-facing side 108) are visible. FIG. 4 illustrates a perspective view of rack-side blind-mate adapter 106 mechanically coupled to chassis 100 in which features of a rack-facing side 112 of rack-side blind-mate adapter 106 are visible, in accordance with embodiments of the present disclosure. FIG. 5 illustrates a perspective view of rack-side blind-mate adapter 106 mechanically coupled to chassis 100 in which features of a server-facing side 114 of rack-side blind-mate adapter 106 (which may be on a side of rack-side blind-mate adapter 106 opposite of rack-facing side 112) are visible, in accordance with embodiments of the present disclosure. FIG. 6 illustrates a perspective view of example information handling system server 102 interfacing with a server-side blind-mate adapter 104 and rack-side blind-mate adapter 106, in accordance with embodiments of the present disclosure.

As shown in FIGS. 2 and 3, server-side blind-mate adapter 104 may include a mechanical housing 116 configured to provide a mechanical structure for housing or otherwise mechanically supporting one or more rack-facing electrical connectors 118 (e.g., rack-facing electrical connectors 118A and 118B) and one or more server-facing electrical connectors 120 (e.g., server-facing electrical connectors 120A, 120B, and 120C). Each server-facing electrical connector 120 may be configured to electrically couple to a respective electrically-conductive feature of information handling system server 102. Similarly, each rack-facing electrical connector 118 may be configured to electrically couple to a respective electrically-conductive feature of an electrical infrastructure of chassis 100. Also, as shown in FIG. 3, server-side blind-mate adapter 104 may include an electrical interface (e.g., comprising features 122 shown in FIG. 3) comprising one or more electrically-conductive conduits, each electrically-conductive conduit configured to electrically couple a server-facing electrical connector 120 to a corresponding rack-facing electrical connector 118 in order to electrically couple electrically-conductive features of the electrical infrastructure of chassis 100 to respective electrically-conductive features of information handling system server 102 when server-side blind-mate adapter 104 is mechanically engaged with information handling system server 102 and the electrical infrastructure of chassis 100 (e.g., via rack-side blind-mate adapter 106). For example, such electrical interface may include electrically-conductive conduits for coupling rack-facing electrical connector 118A to server-facing electrical connector 120A, electrically-conductive conduits for coupling rack-facing electrical connector 118B to server-facing electrical connector 120B, and electrically-conductive conduits for coupling rack-facing electrical connector 118B to server-facing electrical connector 120C.

Server-side blind-mate adapter 104 may include one or more mechanical guiding features mechanically coupled to mechanical housing 116, wherein such one or more mechanical features are configured to enforce alignment of server-side blind-mate adapter 104 to chassis 100 when engaging the server-side blind-mate adapter 104 with chassis 100 (e.g., via rack-side blind-mate adapter 106). For example, such mechanical guiding feature may include a guide pin 124 configured to mechanically interact with a corresponding opening of another structural component (e.g., a mating guide pin hole 126 shown in FIGS. 4 and 5). As another example, such mechanical guiding feature may include a mechanical feature configured to mechanically interact with a mechanical guide rail 128 of information handling system server 102. In some embodiments, similar mechanical features may be present on server-side blind-mate adapter 104 to enforce alignment of server-side blind-mate adapter 104 to information handling system server 102.

As shown in FIGS. 4 and 5, rack-side blind-mate adapter 106 may include a mechanical housing 130 configured to provide a mechanical structure for housing or otherwise mechanically supporting one or more rack-facing electrical connectors 132 (e.g., rack-facing electrical connectors 132A, 132B, and 132C) and one or more server-facing electrical connectors 120 (e.g., server-facing electrical connectors 134A and 134B). Each server-facing electrical connector 134 may be configured to electrically couple to a respective electrically-conductive feature of information handling system server 102 (e.g., via corresponding features of server-side blind-mate adapter 104). Similarly, each rack-facing electrical connector 132 may be configured to electrically couple to a respective electrically-conductive feature of an electrical infrastructure of chassis 100. For example, the rack-facing interface comprising rack-facing electrical connectors 132 may be configured to electrically couple and mechanically couple to a pre-wired interface structure of chassis, such pre-wired interface structure comprising one or more pre-wired cables 136 (e.g., cables 136A, 136B, and 136C) inserted into corresponding electrical connectors 132.

Also, as shown in FIG. 5, rack-side blind-mate adapter 106 may include an electrical interface (e.g., comprising features 138 shown in FIG. 4) comprising one or more electrically-conductive conduits, each electrically-conductive conduit configured to electrically couple a server-facing electrical connector 134 to a corresponding rack-facing electrical connector 132 in order to electrically couple electrically-conductive features of the electrical infrastructure of chassis 100 to respective electrically-conductive features of information handling system server 102 when server-side blind-mate adapter 104 is mechanically engaged with information handling system server 102 and the electrical infrastructure of chassis 100 (e.g., via rack-side blind-mate adapter 106). For example, such electrical interface may include electrically-conductive conduits for coupling rack-facing electrical connectors 132A to server-facing electrical connector 134A, electrically-conductive conduits for coupling rack-facing electrical connectors 132B to server-facing electrical connector 134B, and electrically-conductive conduits for coupling rack-facing electrical connectors 132C to server-facing electrical connector 134B.

Accordingly, as shown in FIG. 6, an electrical interface of information handling system server 102 may mechanically and electrically couple to server-facing electrical connectors 120, rack-facing electrical connectors 118 may electrically couple to server-facing electrical connectors 134, and rack-facing electrical connectors 132 may electrically couple to a pre-wired interface structure of chassis 100, such that together, server-side blind-mate adapter 104 and rack-side blind-mate adapter 106 serve the purpose of enforcing mechanical alignment such that the electrical interface of information handling system server 102 accurately couples both mechanically and electrically to the pre-wired interface structure of chassis 100.

Thus, in a particular use case, an information handling system server 102 already electrically and mechanically coupled to an appropriate server-side blind-made adapter 104 may be shipped to a desired location, and an individual at such location (e.g., courier delivery person or information technology technician) may insert the combination information handling system server 102 and server-side blind-made adapter 104 into a chassis 100 having rack-side blind-mate adapter 106 coupled to the pre-wired interface structure of chassis 100. During such insertion, mechanical features of information handling system server 102 and server-side blind-made adapter 104 may enforce alignment such that server-side blind-made adapter 104 effectively mates with rack-side blind-made adapter 106, thus ensuring proper electrical coupling of information handling system server 102 to the pre-wired interface structure of chassis 100.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An apparatus for coupling an information handling system server to an electrical infrastructure of an information handling system rack, the apparatus comprising:
a mechanical housing;
a server-facing interface on a first side of the mechanical housing and comprising one or more server-facing electrical connectors each configured to electrically couple to a respective electrically-conductive feature of the information handling system server;
a rack-facing interface on a second side of the mechanical housing comprising one or more rack-facing electrical connectors each configured to electrically couple to a respective electrically-conductive feature of the electrical infrastructure; and
an intermediate electrical interface comprising one or more electrically-conductive conduits, each electrically-conductive conduit configured to electrically couple a server-facing electrical connector to a corresponding rack-facing electrical connector in order to electrically couple electrically-conductive features of the electrical infrastructure to respective electrically-conductive features of the information handling system server when the apparatus is mechanically engaged with the information handling system server and the electrical infrastructure.

2. The apparatus of claim 1, wherein the first side is opposite of the second side.

3. The apparatus of claim 1 further comprising a mechanical guiding feature mechanically coupled to the mechanical housing configured to enforce alignment of the apparatus to the information handling system rack when engaging the apparatus to the information handling system rack.

4. The apparatus of claim 3, wherein the mechanical guiding feature comprises a guide pin configured to mechanically interact with a corresponding opening of another structural component.

5. The apparatus of claim 3, wherein the mechanical guiding feature comprises a mechanical feature configured to mechanically interact with a mechanical guide rail.

6. The apparatus of claim 1, wherein the rack-facing interface is configured to electrically couple and mechanically couple to a pre-wired interface structure of the information handling system rack.

7. The apparatus of claim 1 further comprising a mechanical guiding feature mechanically coupled to the mechanical housing configured to enforce alignment of the apparatus to the information handling system server when engaging the apparatus to the information handling system server.

8. The apparatus of claim 7, wherein the mechanical guiding feature comprises a guide pin opening configured to mechanically interact with a corresponding guide pin of the information handling system server.

9. The apparatus of claim 7, wherein the mechanical guiding feature comprises a mechanical feature configured to mechanically interact with a guide rail of the information handling system server.

10. The apparatus of claim 1, wherein the server-facing interface is configured to electrically couple and mechanically couple to the information handling system server.

11. A method for coupling an information handling system server to an electrical infrastructure of an information handling system rack, the method comprising:
providing a mechanical housing;
forming a server-facing interface on a first side of the mechanical housing, the server-facing interface comprising one or more server-facing electrical connectors each configured to electrically couple to a respective electrically-conductive feature of the information handling system server;
forming a rack-facing interface on a second side of the mechanical housing, the rack-facing interface comprising one or more rack-facing electrical connectors each configured to electrically couple to a respective electrically-conductive feature of the electrical infrastructure; and
forming an intermediate electrical interface comprising one or more electrically-conductive conduits, each electrically-conductive conduit configured to electrically couple a server-facing electrical connector to a corresponding rack-facing electrical connector in order to electrically couple electrically-conductive features of the electrical infrastructure to respective electrically-conductive features of the information handling system server when the apparatus is mechanically engaged with the information handling system server and the electrical infrastructure.

12. The method of claim 11, further comprising forming the server-facing interface opposite of the rack-facing interface.

13. The method of claim 11, further comprising forming a mechanical guiding feature mechanically coupled to the mechanical housing configured to enforce alignment of the apparatus to the information handling system rack when engaging the apparatus to the information handling system rack.

14. The method of claim 11, further comprising configuring the rack-facing interface to electrically couple and mechanically couple to a pre-wired interface structure of the information handling system rack.

15. The method of claim 11, further comprising forming a mechanical guiding feature mechanically coupled to the mechanical housing configured to enforce alignment of the apparatus to the information handling system server when engaging the apparatus to the information handling system server.

16. The method of claim 11, further comprising configuring the server-facing interface to electrically couple and mechanically couple to the information handling system server.

17. An information handling system rack comprising:
an electrical infrastructure;
an information handling system server; and
a blind-mate connector for coupling an information handling system server to an electrical infrastructure of an information handling system rack, the blind-mate connector comprising:
a mechanical housing;
a server-facing interface on a first side of the mechanical housing and comprising one or more server-facing electrical connectors each configured to electrically couple to a respective electrically-conductive feature of the information handling system server;
a rack-facing interface on a second side of the mechanical housing comprising one or more rack-facing electrical connectors each configured to electrically couple to a respective electrically conductive feature of the electrical infrastructure; and
an intermediate electrical interface comprising one or more electrically-conductive conduits, each electrically-conductive conduit configured to electrically couple a server-facing electrical connector to a corresponding rack-facing electrical connector in order to electrically couple electrically-conductive features of the electrical infrastructure to respective electrically-conductive features of the information handling system server when the blind-mate connector is mechanically engaged with the information handling system server and the electrical infrastructure.

18. The information handling system rack of claim 17, the blind-mate connector further comprising a mechanical guiding feature mechanically coupled to the mechanical housing configured to enforce alignment of the blind-mate connector to the information handling system rack when engaging the blind-mate connector to the information handling system rack.

19. The information handling system rack of claim 17, the blind-mate connector of claim 17, wherein the rack-facing interface is configured to electrically couple and mechanically couple to a pre-wired interface structure of the information handling system rack.

20. The information handling system rack of claim 17, the blind-mate connector of claim 17, wherein the server-facing interface is configured to electrically couple and mechanically couple to the information handling system server.
